(19) United States
(12) Patent Application Publication
(10) Pub. No.: US 2026/0005118 A1
(43) Pub. Date: Jan. 1, 2026

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventor: Kenji NISHIKAWA, Kanagawa (JP)

(73) Assignee: Amkor Technology Singapore Holding Pte. Ltd., Valley Point #12-03 (SG)

(21) Appl. No.: 18/754,935

(22) Filed: Jun. 26, 2024

(51) Int. Cl. H01L 23/498; H01L 21/56; H01L 23/00; H01L 23/31; H01L 23/367

(52) U.S. Cl. CPC H01L 23/49838; H01L 21/565; H01L 23/3121; H01L 23/3672; H01L 24/32; H01L 24/37; H01L 24/40; H01L 24/45; H01L 24/48; H01L 2224/32245; H01L 2224/37124; H01L 2224/37147; H01L 2224/40245; H01L 2224/45124; H01L 2224/45144; H01L 2224/45147; H01L 2224/48245; H01L 2224/73263; H01L 2224/73265; H01L 2924/1815

(57) ABSTRACT

In one example, an electronic device includes a die paddle and leads. An electronic component is coupled to the die paddle and to the leads. A heat sink is coupled to the electronic component. An encapsulant covers the die paddle, the leads, the electronic component, and the heat sink. The encapsulant comprises an encapsulant top side, an encapsulant bottom side opposite to the encapsulant top side, an encapsulant lateral side connecting the encapsulant top side to the encapsulant, and a top extension region. A top side of the heat sink is exposed from the encapsulant top side. A bottom side of the die paddle is exposed from the encapsulant bottom side. Parts of the leads are exposed from the encapsulant lateral side. The top extension region of the encapsulant covers a top side peripheral edge of the heat sink. Other examples and related methods are also disclosed herein.

### CROSS-REFERENCE TO RELATED APPLICATIONS

Not applicable.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A, 2B, 2C, and 2D show cross-sectional views of an example method for manufacturing an example electronic device.

FIG. 3 shows a cross-sectional view of an example electronic device.

FIG. 4 shows a cross-sectional view of an example electronic device.

FIGS. 5A and 5B show a cross-sectional view and top view (X-ray view), respectively, of an example electronic device.

FIGS. 6A and 6B show cross-sectional views of an example method for manufacturing an example electronic device.

FIGS. 7A and 7B show a cross-sectional view and top view, respectively, of an example electronic device.

FIGS. 8A and 8B show cross-sectional views of an example method for manufacturing an example electronic device.

FIGS. 9A and 9B show cross-sectional views of an example method for manufacturing an example electronic device.

FIGS. 10A and 10B show cross-sectional views of an example method for manufacturing an example electronic device.

The following discussion provides various examples of semiconductor devices and methods for manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to a mechanical coupling or an electrical coupling.

### DESCRIPTION

The present description includes, among other features, structures and associated methods that relate to packaged electronic devices having improved manufacturability and quality. More particularly, structures and methods are described that compensate for dimensional variations and protect exposed surfaces of components, such as heat sinks or die pads, during manufacturing thereby reducing defects and damage to the components. In some examples, structures are provided that cover sensitive regions of the components. In some examples, molded structures are provided that include extension portions that overlap corner portions and laterally overlap peripheral edge portions of the components. In some examples, the extension portions can be used with a mold apparatus during molding to apply pressure to sensitive portions of the components to suppress the formation of burrs and other defects thereby improving quality. In some examples, the molded structures include protruding portions that can be used for more accurate alignment with other structures, such as assembly boards or other electronic devices, thereby improving manufacturability. In addition, the protrusions and the extensions can compensate for non-flat components and other imperfections to further improve manufacturability.

In some applications, electronic devices, such as semiconductor dies, can be encapsulated within a plastic package, protecting the same from hostile environments, and enables electrical interconnection of the semiconductor dies to the next level of assembly, such as a printed circuit board (PCB) or a motherboard. Package components typically include a conductive substrate, such as a metal leadframe, an integrated circuit or a semiconductor die, a bonding material for attaching the semiconductor die to the leadframe, interconnects electrically connect bond pads of the semiconductor die to individual leads of the leadframe, and an encapsulant material surrounding the components and forms the external shape of a semiconductor package, commonly referred to as a package body.

The leadframe is a central support structure of a package and can typically be manufactured by chemically etching or mechanical stamping a metal strip. Part of the leadframe can be inside the package and can be surrounded by a plastic encapsulant or a package body. Some of leads of the leadframe can extend outward from the package body or can be partially exposed for use in electrically connecting the package to other components.

In some examples, the present disclosure relates to an electronic package having electronic components, such as semiconductor components, power components, and/or passive components. In some examples, examples of semiconductor packages related to the present disclosure can comprise ExposedPad (ePad) Low-profile Quad Flat Package (LQFP)/Thin Quad Flat Pack (TQFP), ePAD Thin Shrink Small Outline Package (TSSOP)/Small Outline IC Package (SOIC)/Shrink Small-Outline Package (SSOP), LQFP, microLeadframe®, Metric Quad Flat Pack (MQFP), Plastic Leaded Chip Carrier (PLCC), Small Outline IC Package (SOIC), Small Outline Transistor (SOT)/Thin Small Outline Transistor (TSOT), Shrink Small-Outline Package (SSOP)/Quarter-Size Small Outline Package (QSOP), TQFP, TSOP, TSSOP/Mini Small Outline Package (MSOP). These packages can comprise a conductive substrate, such as a leadframe with die attach pads, and can be exposed, protruded, or encapsulated outwardly. For example, these packages include conductive materials such as copper, nickel, gold, silver, palladium, iron, among other structures in integrated leadframes, and insulating materials such as epoxy mold compounds.

In addition, by mounting electronic devices on a board, an electronic module performing various electrical/electronic functions can be provided. In some examples, the electronic module may implement a memory semiconductor module, a system semiconductor module, a graphics processing unit (GPU) module, a central processing unit (CPU) module, or a power semiconductor module. These electronic modules can comprise various electronic devices to suit various purposes and can also comprise various structures provided on a board. Although the following description focuses on various leaded leadframe based examples, a person skilled in the art will appreciate the same implementation principles can be applied to leadless leadframe packages.

Although leadframe type substrates are tended to be used in the description of the present disclosure, it should be understood that the disclosure also applies to other types of substrates, including, for example, a laminate substrate and other substrates known to those skilled in the art.

In an example, an electronic device includes a substrate including a die paddle with a top side, a bottom side opposite to the top side, a lateral side connecting the top side of the die paddle to the bottom side of the die paddle, and a bottom side peripheral edge; and leads spaced apart from the die paddle. An electronic component includes a component top side and a component bottom side opposite to the component top side, wherein the component bottom side is coupled to the top side of the die paddle; and the electronic component is coupled to the leads. A heat sink coupled to the component top side and includes a top side, a bottom side opposite to the top side of the heat sink, a lateral side connecting the top side of the heat sink to the bottom side of the heat sink, and a top side peripheral edge. An encapsulant covers the die paddle, the leads, the electronic component, and the heat sink. The encapsulant comprises an encapsulant top side, an encapsulant bottom side opposite to the encapsulant top side, an encapsulant lateral side connecting the encapsulant top side to the encapsulant, and a top extension region. The top side of the heat sink is exposed from the encapsulant top side. The bottom side of the die paddle is exposed from the encapsulant bottom side. Parts of the leads are exposed from the encapsulant lateral side. The top extension region of the encapsulant covers the top side peripheral edge of the heat sink.

In an example, an electronic device includes a die pad including a top side, a bottom side opposite to the top side, a lateral side connecting the top side of the die pad to the bottom side of the die pad, and a bottom side peripheral edge. Leads are spaced apart from the die pad. An electronic component is coupled to the leads and comprising a component top side and a component bottom side opposite to the component top side, the component bottom side coupled to the top side of the die pad. A heat sink includes a top side, a bottom side opposite to the top side of the heat sink, a lateral side connecting the top side of the heat sink to the bottom side of the heat sink, and a top side peripheral edge, the bottom side of the heat sink is coupled to the component top side. An encapsulant covering the die pad, the leads, the electronic component, and the heat sink. The encapsulant includes an encapsulant top side, an encapsulant bottom side opposite to the encapsulant top side, an encapsulant lateral side connecting the encapsulant top side to the encapsulant, a top extension region, and a bottom extension region. The top side of the heat sink is exposed from the encapsulant top side. The bottom side of the die pad is exposed from the encapsulant bottom side. Parts of the leads are exposed from the encapsulant lateral side. The top extension region of the encapsulant covers the top side peripheral edge of the heat sink. The bottom extension region of the encapsulant covers the bottom side peripheral edge of the die pad.

In an example, a method of manufacturing an electronic device includes providing a substrate including a die paddle comprise a top side, a bottom side opposite to the top side, a lateral side connecting the top side of the die paddle to the bottom side of the die paddle, and a bottom side peripheral edge; and leads spaced apart from the die paddle. The method includes providing an electronic component comprising a component top side and a component bottom side opposite to the component top side, the component bottom side coupled to the top side of the die paddle. The method includes coupling the electronic component to the leads. The method includes providing a heat sink comprising a top side, a bottom side opposite to the top side of the heat sink, a lateral side connecting the top side of the heat sink to the bottom side of the heat sink, and a top side peripheral edge, the bottom side of the heat sink coupled to the component top side. The method includes providing an encapsulant covering the die paddle, the leads, the electronic component, and the heat sink. In the present example, the encapsulant comprises an encapsulant top side, an encapsulant bottom side opposite to the encapsulant top side, an encapsulant lateral side connecting the encapsulant top side to the encapsulant, and a top extension region; the top side of the heat sink is exposed from the encapsulant top side; the bottom side of the die paddle is exposed from the encapsulant bottom side; parts of the leads are exposed from the encapsulant lateral side; and the top extension region of the encapsulant covers the top side peripheral edge of the heat sink.

Other examples are included in the present disclosure. Such examples may be found in the figures, in the claims, or in the description of the present disclosure.

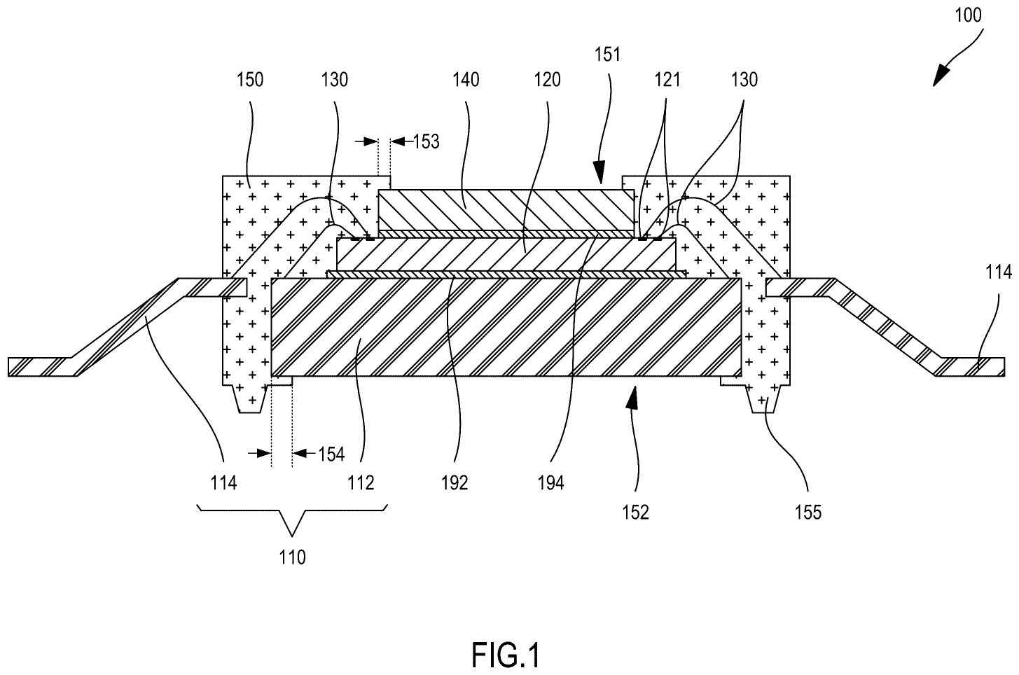

FIG. 1 shows a cross-sectional view of an example electronic device 100. In the example shown in FIG. 1, electronic device 100 can comprise substrate 110, electronic component 120, component interconnects 130, heat sink 140, and encapsulant 150. In some examples, electronic device 100 can comprise die attach material 192 or heat sink attach material 194.

Substrate 110 can comprise or be referred to as a leadframe or a molded substrate. In some examples, substrate 110 can comprise die paddle 112 and a plurality of leads 114 located around and spaced apart from one or more sides of die paddle 112. Die paddle 112 comprises a top side, a bottom side opposite to the top side, a lateral side connecting the top side of the die paddle to the bottom side of the die paddle, and a bottom side peripheral edge. Die paddle 112 can comprise or be referred to as a die pad, a heat sink, or a heat spreader. In some examples, die paddle 112 can be relatively thicker than leads 114 or a portion of leads 114. In some examples, some regions of die paddle 112 can be located inside and covered by encapsulant 150 and other regions can be exposed from encapsulant 150. Leads 114 can comprise or be referred to as terminals, contacts, input/output pins, or input/output legs. In some examples, leads 114 can be bent at least once, and some regions of leads 114 can be located inside and covered by encapsulant 150 and other regions can be exposed from or protrude outside encapsulant 150.

Substrate 110 can comprise a conductive material, for example, a metal or metal alloy, such as a copper (Cu), Cu alloy, iron (Fe), Fe alloy, etc. In some examples, substrate 110 can be manufactured by chemical etching or mechanical stamping of a metal strip. In some examples, the thickness of die paddle 112 can range from approximately 100 micrometers (μm) to approximately 2000 μm and the thickness of leads 114 can range from approximately 100 μm to approximately 1250 μm. It is understood that some of leads 114 can have different thicknesses than other leads 114. For example, leads used to carry higher current can be thicker than leads used to carry lower currents or control signals. Substrate 110 can support electronic component 120 on die paddle 112 and can also provide an electrical path (e.g., a signal path or power path) between electronic component 120 and a next level of assembly, such as an external board. In some examples, the area of substrate 110 can range from approximately 5 millimeters (mm)×5 mm to approximately 60 mm×60 mm, and the thickness of substrate 110 can range from approximately 100 μm to approximately 2000 μm.

Electronic component 120 can be provided on die paddle 112. Electronic component 120 can comprise a component top side and a component bottom side opposite to the component top side and coupled to die paddle 112. Electronic component 120 can comprise component bond pads 121 adjacent to the component top side. Electronic component 120 can comprise or be referred to as a die, a chip, a power device, a package, or a passive device. In addition, the die or the chip can comprise a semiconductor integrated circuit (IC) die manufactured as part of semiconductor wafer and later separated into individual die. In some examples, electronic component 120 can comprise a digital signal processor (DSPs), a network processor, a power management unit, an audio processor, a wireless baseband system on a chip (SoC) processor, a sensor, an application specific integrated circuit, a memory, an antenna on package (AoP), an antenna in package (AiP), a 5G NR mmWave module, a sub-6 GHz RF module or an Integrated passive device (IPD). In some examples, the area of electronic component 120 can range from approximately 1 mm×1 mm to approximately 20 mm×20 mm, and the thickness of electronic component 120 can range from approximately 50 μm to approximately 775 μm. In some examples, electronic component 120 can perform various calculations and control processing, store data, remove noise from an electrical signal, transmit/receive radio frequencies, or amplify electrical current or voltage.

In some examples, the component bottom side of electronic component 120 can be attached to die paddle 112 through die attach material 192. Die attach material 192 can comprise or be referred to as an adhesive, an attachment tape, or an attachment film. In some examples, die attach material 192 can be provided on die paddle 112, and electronic component 120 can be attached to die attach material 192. In some examples, die attach material 192 can be provided on electronic component 120, and electronic component 120 can be attached to die paddle 112. In some examples, the thickness of die attach material 192 can range from approximately 1 μm to approximately 5 μm. Die attach material 192 is configured to affix electronic component 120 to die paddle 112 and can comprise a thermally or electrically conductive material.

Component interconnects 130 can electrically connect bond pads 121 of electronic component 120 to leads 114 or die paddle 112. Interconnects 130 can comprise conductive wires, such as gold (Au) wires, Cu wires, or aluminum (Al) wires. In some examples, first ends of interconnects 130 can be ball-bonded to bond pad 121 and second ends of the interconnects 130 can be stitch-bonded to leads 114 or die paddle 112 using wire bonding equipment. The reverse of this process can also be used where the first ends of interconnects 130 can be ball-bonded to leads 114 or die paddle 112 and the second ends can be stitched-bonded to bond pads 121. In some examples, interconnects 130 can also comprise conductive clips, such as Cu clips or Al clips. In some examples, the first ends of interconnects 130 can be soldered to bond pad 121 and the second ends of interconnects 130 can be soldered to leads 114 or die paddle 112. In some examples, the lengths of interconnects 130 can range from approximately 1 mm to approximately 10 mm, and the diameters or thicknesses of interconnects 130 can range from approximately 10 μm to approximately 50 μm. Interconnects 130 can provide a current flow path between electronic component 120 and leads 114 or can provide a current flow path between electronic component 120 and die paddle 112.

Electronic device 100 comprises heat sink 140 coupled to the top side of electronic component 120. Heat sink 140 can comprise a top side, a bottom side opposite to the top side, and a lateral side connecting the top side of heat sink 140 to the bottom side of heat sink 140, and a top side peripheral edge. In some examples, heat sink 140 comprises a smaller width than electronic component 120 so heat sink 140 does not overlap component bond pads 121. Heat sink 140 can comprise or be referred to as a heat dissipation plate or a heat spreader. Heat sink 140 can be provided using a metal such as Al, Cu, silver (Ag), Au, etc., or a metal alloy, such as an Al alloy, Cu alloy, Ag alloy, Au alloy, etc. In some examples, heat sink 140 can be attached to the top side of electronic component 120 through heat sink attach material 194. Heat sink attach material 194 can comprise or be referred to as an adhesive, an attachment tape, an attachment film, a thermal interface material (TIM), or a solder. In some examples, heat sink attach material 194 can be provided on electronic component 120, and heat sink 140 can be attached to heat sink attach material 194. In some examples, heat sink attach material 194 can be provided on heat sink 140, and heat sink 140 can be attached onto electronic component 120. In some examples, the thickness of heat sink attach material 194 can range from approximately 1 μm to approximately 5 μm. Heat sink attach material 194 is configured to securely affix heat sink 140 onto electronic component 120 and can comprise a thermally conductive material. The thickness of heat sink 140 can range from approximately 50 μm to approximately 1000 μm. Heat sink 140 is configured to radiate heat generated from electronic component 120 outward.

Electronic device 100 comprises encapsulant 150 that covers substrate 110, electronic component 120, interconnects 130, and heat sink 140. Encapsulant 150 can comprise an encapsulant top side proximate to heat sink 140, an encapsulant bottom side proximate to the die paddle 112, and encapsulant lateral side connecting the encapsulant top side to the encapsulant bottom side. Some regions of leads 114 can be located inside encapsulant 150, and remaining regions of leads 114 can be exposed from or be located outside encapsulant 150. Some regions of die paddle 112 can be located inside encapsulant 150, and some other regions of die paddle 112 can be exposed from encapsulant 150. Some regions of heat sink 140 can be located inside encapsulant 150, and some other regions of heat sink 140 can be exposed from encapsulant 150. Encapsulant 150 can comprise top opening 151, bottom opening 152, top extension region 153, bottom extension region 154, and bottom protrusion 155.

In some examples, a portion of the top side of heat sink 140 can be exposed from encapsulant 150 through top opening 151. The lateral sides of heat sink 140 can be covered and surrounded by encapsulant 150. The upper circumference, upper edge, or top side peripheral edge of heat sink 140 can be covered and surrounded by top extension region 153 of encapsulant 150. In some examples, the top side of encapsulant 150 can be elevated with respect to the top side of heat sink 140 so that these top sides are not coplanar.

In some examples, a portion of the bottom side of die paddle 112 can be exposed from encapsulant 150 through bottom opening 152. The lateral sides of die paddle 112 can be covered and surrounded by encapsulant 150. The lower circumference, lower edge, or bottom side peripheral edge of die paddle 112 can be surrounded by bottom extension region 154 of encapsulant 150. In the present example, the bottom side of encapsulant 150 extends lower than the bottom side of die paddle 112 so that these sides are not coplanar. Bottom protrusion 155 of encapsulant 150 can protrude downward from bottom extension region 154 of encapsulant 150. The bottom side or tip of bottom protrusion 155 of encapsulant 150 can be lower than the bottom side of bottom extension region 154 of encapsulant 150. Bottom protrusion 155 is configured to assist in connecting electronic device 100 to a next level of assembly.

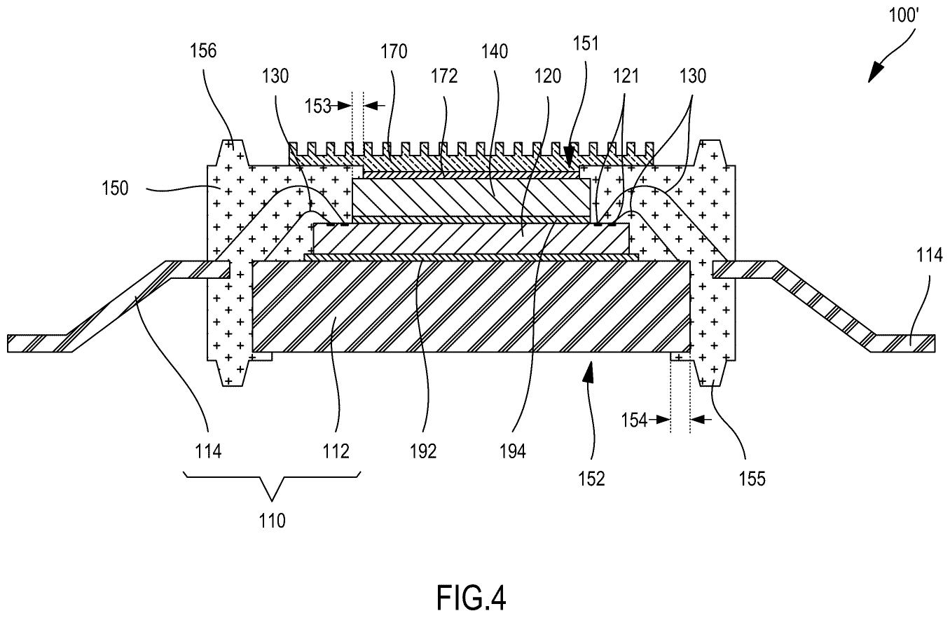

In some examples, a top protrusion can also be provided on the top side of encapsulant 150 (see e.g., FIG. 4). The top protrusion can protrude upward from top extension region 153 of encapsulant 150. The top side or tip of the top protrusion of encapsulant 150 can be higher than the top side of top extension region 153 of encapsulant 150. Similar to bottom protrusion 155, the top protrusion is configured to assist in connecting electronic device 100 to a next level of assembly.

Encapsulant 150 can comprise or be referred to as a package body, an encapsulating structure, an epoxy molding compound, a resin, a filler-reinforced polymer, a B-stage compressed film, or gel. In some examples, encapsulant 150 can be provided by transfer molding, compression molding, transfer molding, liquid encapsulant molding, vacuum lamination, paste printing, film assisted molding, or other processes as known to one of ordinary skill in the art. Transfer molding can include a process of supplying a resin around substrate 110 using a gate (a supply port), and compression molding can include a process of supplying a fluid resin to a mold in advance and then putting substrate 110 into the mold to harden the fluid resin. After this process, the cured encapsulant 150 can be ejected from the mold. In some examples, the area of encapsulant 150 can range from approximately 5 mm×5 mm to approximately 70 mm×70 mm, and the thickness of encapsulant 150 can range from approximately 0.9 mm to approximately 10 mm. Encapsulant 150 can isolate and protect the substrate 110, electronic component 120, interconnects 130, and heat sink 140 from external environments.

Although electronic device 100 comprises an exposed type of package where various elements are exposed from encapsulant 150, the top side or bottom side of encapsulant 150 may not be flat because of, for example, stacking variations between the various components. In accordance with the present description, bottom protrusion 155 provided on the bottom side of encapsulant 150 can compensate for such variations and electronic device 100 can be more accurately mounted to a next level of assembly, such as an external board. In addition, electronic device 100 can be covered and surrounded by encapsulant 150 around sensitive exposed areas, which can include the exposed bottom side of die paddle 112 covered by bottom extension region 154 or the exposed top side of heat sink 140 covered by top extension region 153. Accordingly, edge defects, such as burrs in die paddle 112 or heat sink 140 can be suppressed or covered and surrounded by encapsulant 150 thereby reducing the effects of such defects on the manufacturability and quality of electronic device 100.

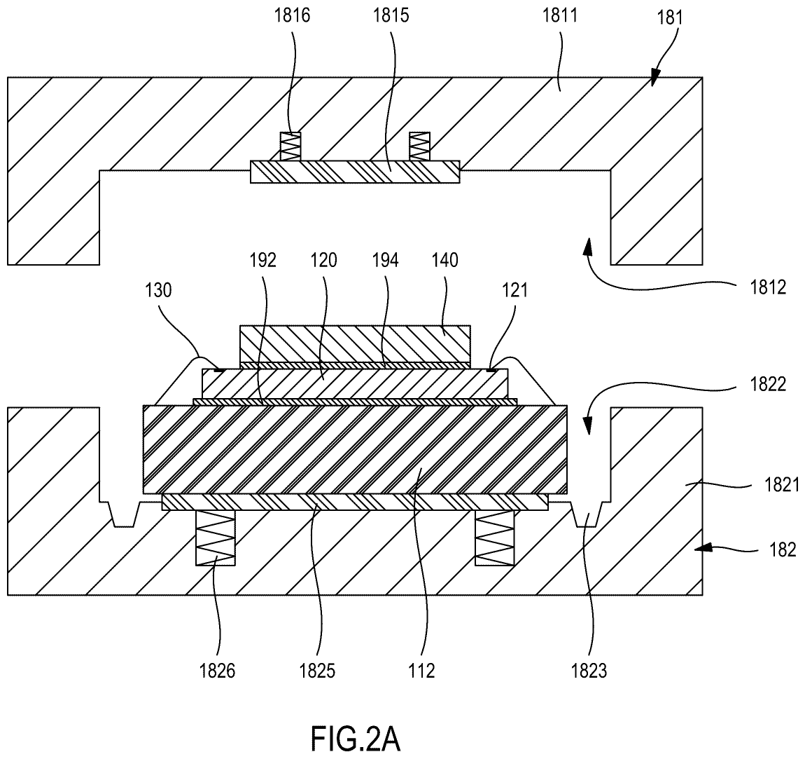

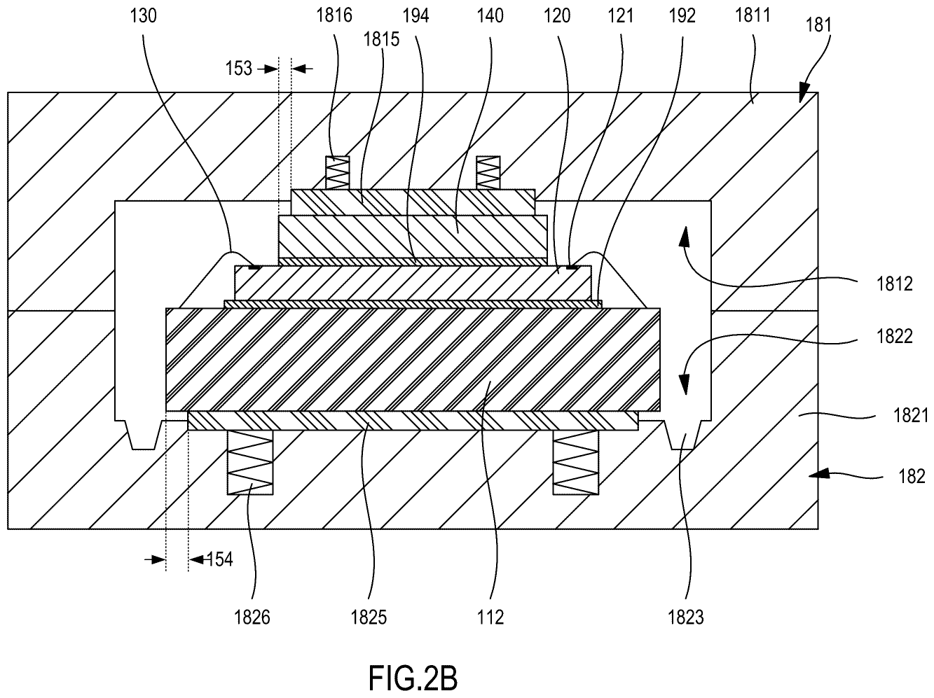

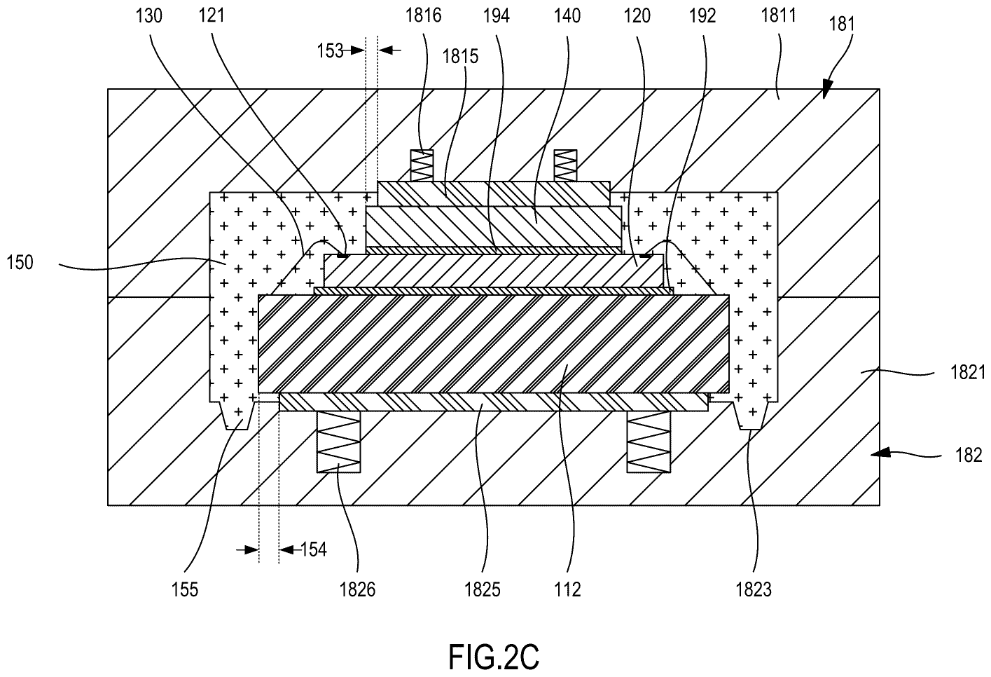

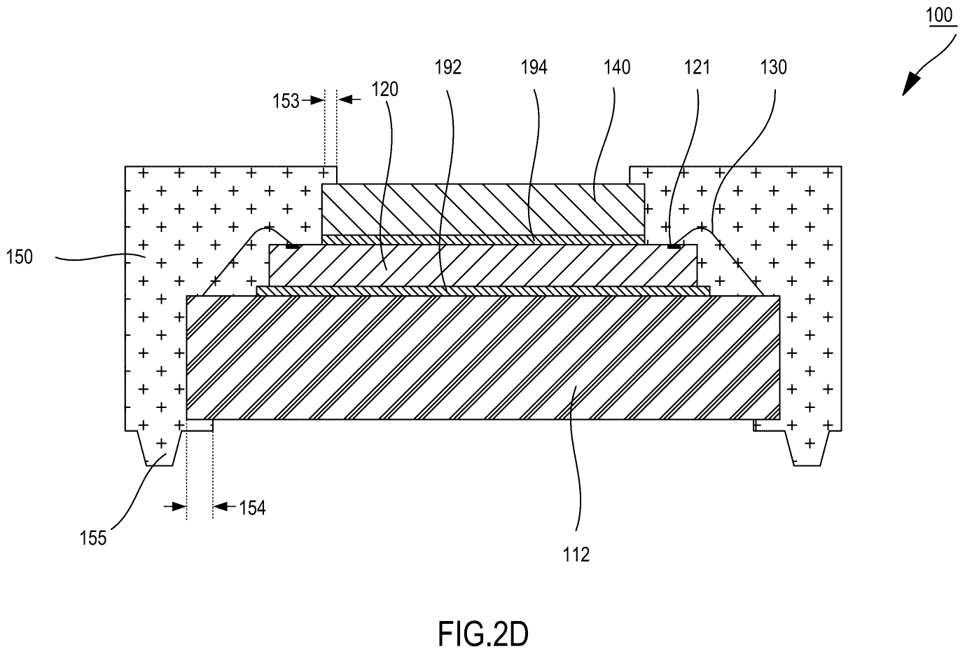

FIGS. 2A, 2B, 2C, and 2D show cross-sectional views of an example method for manufacturing an electronic device, such as electronic device 100. To simplify the present description, leads 114 of substrate 110 are not shown in FIGS. 2A-2D. FIG. 2A shows a cross-sectional view of electronic device 100 at an early stage of manufacture including die paddle 112, electronic component 120, interconnects 130, and heat sink 140 prior to providing encapsulant 150. In the example shown in FIG. 2A, electronic device 100 is placed between upper die set 181 and lower die set 182 of a mold apparatus.

In some examples, upper die set 181 can comprise upper die body 1811, upper cavity 1812 recessed inward from the lower side of upper die body 1811, upper holding plate 1815 provided on the upper side of upper cavity 1812, upper holding plate 1815 provided on the upper side of upper cavity 1812, and upper spring 1816 provided coupled between upper holding plate 1815 and upper die body 1811. In some examples, upper holding plate 1815 can protrude downward from the upper side of upper cavity 1812. In some examples, the upper side and the lateral sides provided in the vertical direction from the upper side of cavity 1812 can be flat. In other examples, these sides can comprise other shapes.

In some examples, lower die set 182 can comprise lower die body 1821, lower cavity 1822 recessed inward from the upper side of lower die body 1821, lower holding plate 1825 provided on the lower side of lower cavity 1822, and lower springs 1826 coupled between lower holding plate 1825 and lower die body 1821. In some examples, lower holding plate 1825 can protrude outward from the lower side of lower cavity 1822. In some examples, the lower side and the lateral sides provided in the vertical direction from the lower side of lower cavity 1822 can be flat. In other examples, these sides can comprise other shapes. In some examples, lower recess 1823 having a depth can be provided between the lower side of lower cavity 1822 and the lateral sides. In some examples, the depth of lower recess 1823 can be greater than the thickness of lower holding plate 1825. In some examples, lower recess 1823 can be similar to or correspond to the shape for bottom protrusion 155 of encapsulant 150.

In some examples, electronic device 100 can be placed between upper die set 181 and lower die set 182, which are initially vertically separated and spaced apart from each other. For example, die paddle 112 can be placed on lower holding plate 1825. In some examples, die paddle 112 can be placed in an uneven or non-flat condition inside lower die set 182.

FIG. 2B shows a cross-sectional view of electronic device 100 at a later stage of manufacture. In the example shown in FIG. 2B, upper die set 181 and lower die set 182 can be placed in closed condition and electronic device 100 can be clamped between upper die set 181 and lower die set 182. Upper holding plate 1815 of upper die set 181 can elastically press the top side of heat sink 140 due to an elastic force applied by upper spring 1816. In some examples, the horizontal width of upper holding plate 1815 can be less than the horizontal width of heat sink 140. In some examples, the upper circumference or top side peripheral edge of heat sink 140 can be exposed through the lateral sides of upper holding plate 1815 to provide space for top extension region 153. In some examples, lower holding plate 1825 can elastically press the bottom side of die paddle 112 due to an elastic force applied by lower spring 1826. In some examples, the horizontal width of lower holding plate 1825 can be less than the horizontal width of die paddle 112. In some examples, the lower circumference or bottom side peripheral edge of die paddle 112 can be exposed through the lateral sides of lower holding plate 1825 to provide space for bottom extension region 154. In present example, lower recess 1823 of lower die set 182 are located outside the lateral sides of die paddle 112.

In this way, electronic device 100 can be clamped in an even and flat state between upper die set 181 and lower die set 182. In addition, by the clamping, warpage of electronic device 100 can be reduced and defects caused by burrs can be prevented or reduced.

FIG. 2C shows a cross-sectional view of electronic device 100 at a later stage of manufacture. In the example shown in FIG. 2C, encapsulant 150 can be provided between upper cavity 1812 of upper die set 181 and lower cavity 1822 of lower die set 182. In some examples, molten encapsulant 150 can flow into upper cavity 1812 and lower cavity 1822 through the gate provided in upper die set 181 or lower die set 182. In this way, encapsulant 150 can cover and surround die paddle 112, electronic component 120, interconnects 130, and heat sink 140. In some examples, encapsulant 150 can form top extension region 153 by surrounding the lateral sides of upper holding plate 1815 and the vicinity of the top side of heat sink 140. In some examples, encapsulant 150 can form bottom extension region 154 by surrounding the lateral sides of lower holding plate 1825 and the vicinity of the bottom side of die paddle 112. In some examples, encapsulant 150 can form bottom protrusion 155 protruding downward from the lateral sides of die paddle 112.

FIG. 2D shows a cross-sectional view of electronic device 100 at a later stage of manufacture. In the example shown in FIG. 2D, electronic device 100 provided with encapsulant 150 can be removed from upper die set 181 and lower die set 182. In some examples, after curing of encapsulant 150 is completed, upper die set 181 and lower die set 182 can be separated from each other, and electronic device 100 can be separated from upper die set 181 or lower die set 182. In this way, electronic device 100 is provided comprising heat sink 140 exposed from encapsulant 150 at an upper portion and die paddle 112 exposed from encapsulant 150 at a lower portion. Also, top extension region 153 of encapsulant 150 is provided covering the upper circumference or top side peripheral edge of heat sink 140 and bottom extension region 154 of encapsulant 150 is provided on the lower circumference or bottom side peripheral edge of die paddle 112. In some examples, bottom protrusion 155 of encapsulant 150 is provided on the circumference of or adjacent to bottom extension region 154.

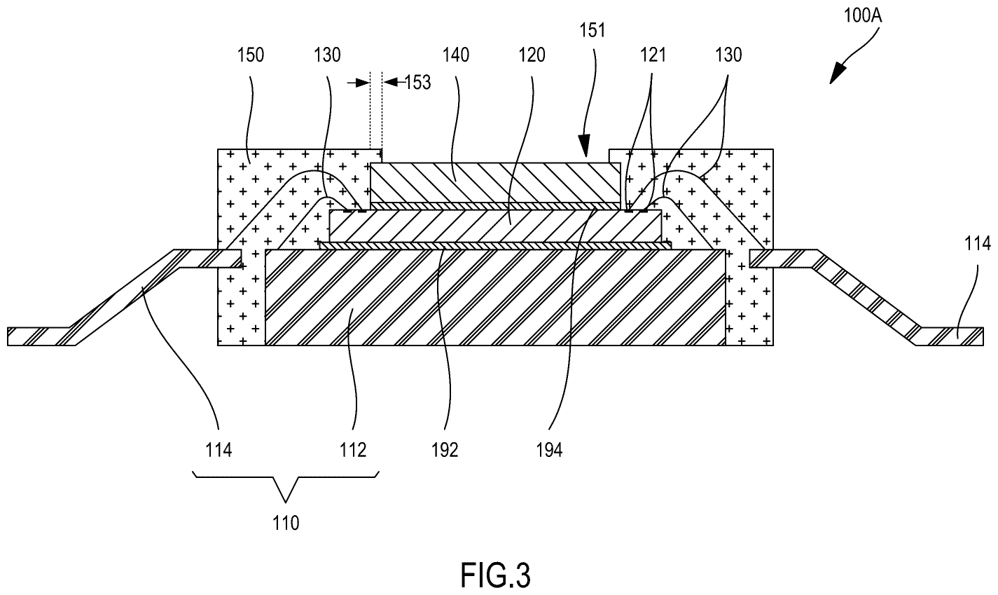

FIG. 3 shows a cross-sectional view of an example electronic device 100A. Electronic device 100A shown in FIG. 3 can be similar to electronic device 100 shown in FIG. 1 except that a bottom extension region or a bottom projection is not provided as part of encapsulant 150. In the example shown in FIG. 3, the entire bottom side of die paddle 112 can be exposed through the bottom side of encapsulant 150. In some examples, the bottom side of the die paddle 112 can be coplanar with the bottom side of encapsulant 150. Electronic device 100A comprises top extension region 153 of encapsulant 150, which covers and surrounds the upper circumference or top side edge of heat sink 140.

FIG. 4 shows a cross-sectional view of an example electronic device 100′. Electronic device 100′ shown in FIG. 4 can be similar to electronic device 100 shown in FIG. 1 except that electronic device 100′ comprises a heat spreader 170 coupled to heat sink 140. In the example shown in FIG. 4, heat spreader 170 can be attached to the top side of heat sink 140. In some examples, the lateral width of heat spreader 170 can be greater than the lateral width of heat sink 140. In some examples, heat spreader 170 can be provided on the top side of encapsulant 150 around heat sink 140 (e.g., top extension region 153). Heat spreader 170 can comprise a plurality of heat radiation fins extending outward to improve heat dissipation performance.

Heat spreader 170 can comprise a metal such as Al, Cu, Ag, Au, etc., or a metal alloy, such an Al alloy, Cu alloy, Ag alloy, Au alloy, etc., In some examples, heat spreader 170 can be attached to heat sink 140 through heat spreader attach material 172. In some examples, heat spreader 170 can be in contact with top extension region 153 of encapsulant 150 or the top side of encapsulant 150. Heat spreader attach material 172 can comprise or be referred to as an adhesive, an attachment tape, an attachment film, a thermal interface material (TIM), or a solder. In some examples, heat spreader attach material 172 can be provided on heat sink 140, and heat spreader 170 can be attached onto heat spreader attach material 172. In some examples, the thickness of heat spreader attach material 172 can range from approximately 1 μm to approximately 5 μm. By attaching heat spreader 170 onto heat sink 140, heat spreader attach material 172 is configured to securely affix heat spreader 170 to heat sink 140 and can comprise a thermally conductive material. In some examples, the thickness of heat spreader 170 can range from approximately 20 μm to approximately 500 μm. Heat spreader 170 is configured to radiate heat generated from electronic component 120 outward.

In some examples, top protrusion 156 can be provided on the top side of encapsulant 150. Top protrusion 156 of encapsulant 150 can protrude upward around top extension region 153 of encapsulant 150. The top side or tip of top protrusion 156 of encapsulant 150 can be higher than the top side of top extension region 153 of encapsulant 150. Electronic device 100′ comprises top extension region 153 of encapsulant 150, which covers and surrounds the upper circumference or top side edge of heat sink 140, and bottom extension region 154 of encapsulant 150, which covers and surrounds the lower circumference or bottom side peripheral edge of die paddle 112. In addition, electronic device 100′ comprises bottom protrusion 155.

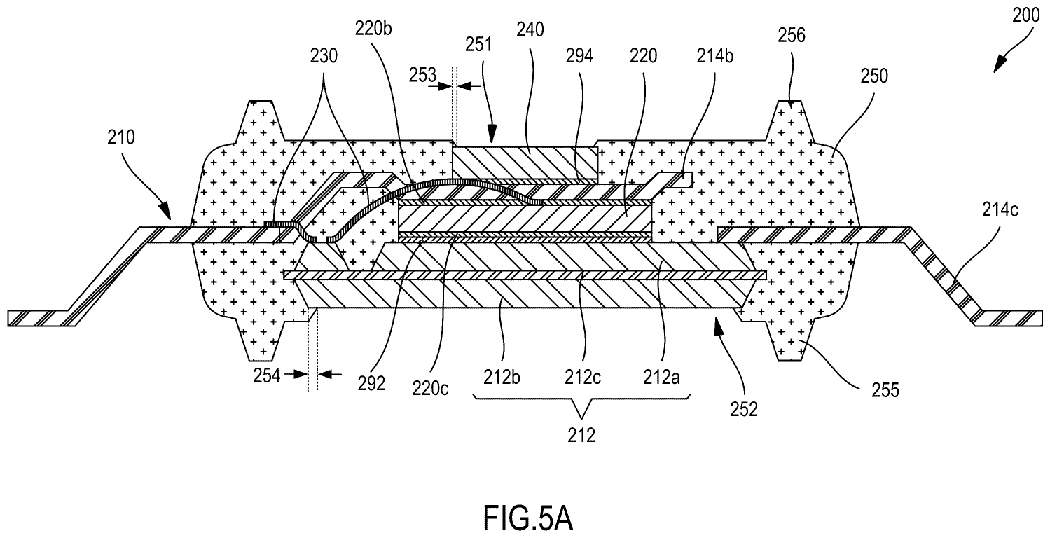

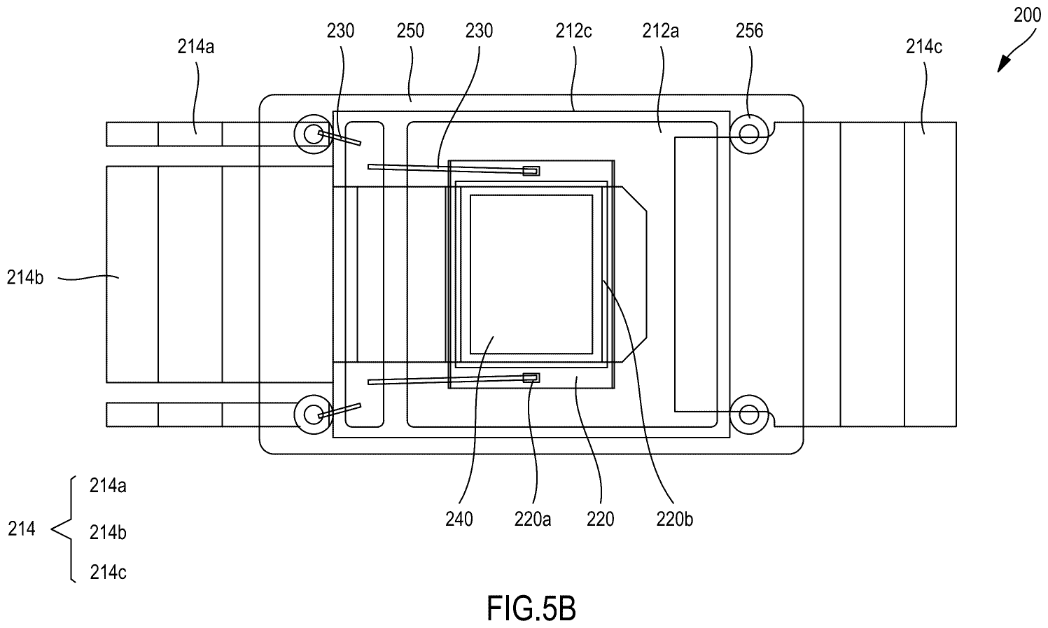

FIGS. 5A and 5B show a cross-sectional view and top view (X-ray view), respectively, of an example electronic device 200. In the example shown in FIGS. 5A and 5B, electronic device 200 can comprise substrate 210, electronic component 220, component interconnects 230, heat sink 240, and encapsulant 250. In some examples, electronic device 200 can comprise die attach material 292 or heat sink attach material 294.

Substrate 210 can comprise or be referred to as a leadframe or a molded substrate. Substrate 210 can comprise die paddle 212 and a plurality of leads 214 laterally separated from die paddle 212.

In the present example, die paddle 212 can comprise or be referred to as a direct copper bonding (DCB) board or an active metal brazing (AMB) board. Die paddle 212 comprises a top side, a bottom side opposite to the top side, a lateral side connecting the top side to the bottom side, and bottom side peripheral edge. Die paddle 212 can comprise upper conductor 212a, lower conductor 212b, and core layer 212c interposed between upper conductor 212a and lower conductor 212b. Upper conductor 212a can comprise or be referred to as a patterned metal layer, such as Cu or a metal foil. In some examples, the thickness of upper conductor 212a can range from approximately 1 μm to approximately 10 μm. Upper conductor 212a can provide a current flow path between electronic component 220 and one or more leads 214. Lower conductor 212b can comprise or be referred to as a patterned metal layer, such as Cu or a metal foil, or a continuous, solid, or uninterrupted metal layer. In some examples, the thickness of lower conductor 212b can range from approximately 1 μm to approximately 10 μm. In some examples, die paddle 212 can comprise vias extending through core layer 212c electrically connecting upper conductor 212a and lower conductor 212b. In this way, lower conductor 212b can provide a current flow path between electronic component 220 and other devices or leads 214. In some examples, lower conductor 212b can be configured as a heat sink. Core layer 212c can comprise a ceramic or dielectric material. In some examples, ceramic can comprise aluminum oxide (Al₂O₃), aluminum nitride (AlN), silicon nitride (SiN), or beryllium oxide (BeO). In some examples, the thickness of upper core layer 212c can range from approximately 1 μm to approximately 10 μm. Core layer 212c can stably support upper conductor 212a and lower conductor 212b. The area of die paddle 212 can range from approximately 5 mm×5 mm to approximately 60 mm×60 mm, and the thickness of die paddle 212 can range from approximately 100 μm to approximately 1100 μm.

In the present example, leads 214 can be coupled to die paddle 212 or electronic component 220. In some examples, leads 214 can comprise gate lead 214a, source lead 214b, and drain lead 214c. Gate lead 214a, source lead 214b, and drain lead 214c can also comprise or be referred to as contacts or terminals. In some examples, leads 214 can be relatively thinner than die paddle 212. Leads 214 can comprise a conductive material such as a Cu alloy or Fe alloy and can be manufactured by chemical etching or mechanical stamping a metal strip. Leads 214 can comprise or be referred to as terminals, contacts, input/output pins, or input/output legs.

In some examples, gate lead 214a can be provided in the form of a thin beam, and part of gate lead 214a can be located inside encapsulant 250 and another part can be exposed from encapsulant 250. In some examples, source lead 214b can be provided in the form of a thin and wide plate or clip and can be coupled to electronic component 220. Part of source lead 214b can be located inside encapsulant 250 and another part can be exposed from encapsulant 250. In some examples, drain lead 214c can be provided in the form of a thin and wide plate or clip and can be coupled to die paddle 212. Part of drain lead 214c can be located inside encapsulant 250 and another part can be exposed from encapsulant 250. In some examples, drain lead 214c can be coupled to upper conductor 212a and the bottom side or drain side of electronic component 220. In some examples, a pair of gate leads 214a and source lead 214b can be provided on one side of encapsulant 250 and drain lead 214c can be provided on an opposing side of encapsulant 250. In some examples, the thickness of leads 214 can range from approximately 100 μm to approximately 1250 μm. Leads 214 can provide conductive pathways for gate signals, source current, and drain current between electronic component 220 and external devices, such as a control IC and a power supply.

Electronic component 220 can be provided on die paddle 212. Electronic component 220 can comprise a component top side and a component bottom side opposite to the component top side and coupled to die paddle 212. Electronic component 220 can comprise or be referred to as a die, chip, a power device, a package, or a passive device. In some examples, electronic component 220 can comprise gate component terminal 220a, source component terminal 220b, and drain component terminal 220c. In some examples, gate component terminal 220a and source component terminal 220b can be provided on the top side of electronic component 220. In some examples, drain component terminal 220c can be provided on the bottom side of electronic component 220. In some examples, the thickness of gate component terminal 220a, source component terminal 220b, and drain component terminal 220c can range from approximately 1 μm to approximately 10 μm. Gate component terminal 220a, source component terminal 220b, and drain component terminal 220c can provide electrical paths for gate signals, source current, and drain current, respectively. The thickness of electronic component 220 can range from approximately 50 μm to approximately 775 μm. As described above, electronic component 220 can allow or block the flow of current from source component terminal 220b to drain component terminal 220c depending on a gate signal input through gate component terminal 220a.

In some examples, drain component terminal 220c of electronic component 220 can be attached to upper conductor 212a (e.g., a drain pattern) on die paddle 212 through die attach material 292. Accordingly, drain component terminal 220c of electronic component 220 can be electrically connected to drain lead 214c through die attach material 292 and die paddle 212. Die attach material 292 can comprise or be referred to as a conductive adhesive, a conductive attach tape, a conductive attach film, or a solder. In some examples, the thickness of die attach material 292 can range from approximately 1 μm to approximately 5 μm. Die attach material 292 can couple electronic component 220 to die paddle 212.

In some examples, source lead 214b can be electrically connected to source component terminal 220b of electronic component 220 through a conductive attachment material (e.g., a conductive adhesive or solder). In some examples, among leads 214, source lead 214b can be electrically connected to source component terminal 220b of electronic component 220 and drain lead 214c can be electrically connected to upper conductor 212a of die paddle 212.

Interconnects 230 can couple gate component terminal 220a of electronic component 220 to gate lead 214a. In some examples, one interconnect 230 can electrically connect gate component terminal 220a of electronic component 220 and a gate pattern portion of upper conductor 212a of die paddle 212. In some examples, another interconnect 230 can electrically connect the gate pattern portion of upper conductor 212a of die paddle 212 and gate lead 214a. Interconnects 230 may include conductive wires such as Au wires, Cu wires, or Al wires. In some examples, first ends of interconnects 230 can be ball-bonded to gate component terminal 220a and second ends of interconnects 230 can be stitch-bonded to the gate pattern portion of upper conductor 212a of die paddle 212 by wire bonding equipment. As described with electronic device 100, the reverse of this process can also be used. In some examples, interconnects 230 can also comprise conductive clips, such as Cu clips or Al clips. In some examples, the lengths of interconnects 230 can range from approximately 1 mm to approximately 10 mm, and the diameters or thicknesses of interconnects 230 can range from approximately 10 μm to approximately 50 μm. Interconnects 230 can provide a gate signal path between gate component terminal 220a of electronic component 220 and gate lead 214a.

In the present example, heat sink 240 can be coupled to a top side of source lead 214b. Heat sink 240 can comprise a top side, a bottom side opposite to the top side, and a lateral side connecting the top side of heat sink 240 to the bottom side of heat sink 240, and a top side peripheral edge. Heat sink 240 can be integrally provided with source lead 214b as a single-piece construction, or can be attached to source lead 214b as a separate component by heat sink attach material 294. In some examples, heat sink attach material 294 can comprise or be referred to as a conductive adhesive, a conductive tape, a conductive film, a TIM, or a solder. In some examples, the horizontal width of the solder can be smaller than the horizontal width of electronic component 220 or the horizontal width of source lead 214b. Heat sink 240 can be provided using an Al alloy, Cu alloy, Ag alloy, or Au alloy. In some examples, the thickness of heat sink 240 can range from approximately 50 μm to approximately 1000 μm. Heat sink 240 is configured to radiate heat generated from electronic component 220 outward via source lead 214b.

Electronic device 200 comprises encapsulant 250 that covers and surround substrate 210, electronic component 220, interconnects 230, and heat sink 240. Encapsulant 250 can comprise an encapsulant top side proximate to heat sink 240, an encapsulant bottom side proximate to the die paddle 212, and encapsulant lateral side connecting the encapsulant top side to the encapsulant bottom side. Some regions of leads 214 can be located inside encapsulant 250, and other regions of leads 214 can be located outside or exposed from encapsulant 250. Some regions of die paddle 212 can be located inside encapsulant 250, and other regions of die paddle 212 (e.g., lower conductor 212b) can be exposed from encapsulant 250. Some regions of heat sink 240 can be located inside encapsulant 250, and other regions of heat sink 240 can be exposed from encapsulant 250. Encapsulant 250 can comprise top opening 251, bottom opening 252, top extension region 253, top protrusion 256, bottom extension region 254, and bottom protrusion 255.

In some examples, a portion of the top side of heat sink 240 can be exposed from encapsulant 250 through top opening 251. The lateral sides of heat sink 240 can be surrounded by encapsulant 250. The upper circumference or the top side peripheral edge of heat sink 240 can be covered and surrounded by top extension region 253 of encapsulant 250. The top side of encapsulant 250 can be higher than the top side of heat sink 240 and top protrusion 256 of encapsulant 250 can protrude upward from top extension region 253 of encapsulant 250. The top side or tip of top protrusion 256 of encapsulant 250 can be higher than or elevated above the top side of top extension region 253 of encapsulant 250.

In some examples, a portion of lower conductor 212b of die paddle 212 can be exposed from encapsulant 250 through bottom opening 252. The lateral sides of die paddle 212 can be covered and surrounded by encapsulant 250. The lower circumference or bottom peripheral edge of lower conductor 212b can be surrounded by bottom extension region 254 of encapsulant 250. The bottom side of encapsulant 250 can be lower than the lower side of lower conductor 212b. Bottom protrusion 255 of encapsulant 250 can protrude downward from bottom extension region 254 of encapsulant 250. The bottom side or tip of bottom protrusion 255 of encapsulant 250 can be lower than the bottom side of bottom extension region 254 of encapsulant 250. The area of encapsulant 250 can range from approximately 5 mm×5 mm to approximately 70 mm×70 mm, and the thickness of encapsulant 250 can range from approximately 0.9 mm to approximately 10 mm. Encapsulant 250 can isolate and protect substrate 210, electronic component 220, interconnects 230, and heat sink 240 from external environments.

Although electronic device 200 comprises an exposed type of package where various elements are exposed from encapsulant 250, the top and bottom sides of encapsulant 250 may not be flat because of, for example, stacking variations between the various components. In accordance with the present description, top protrusion 256 provided on the top side of encapsulant 250 can compensate for such variations and other upper components can be better positioned adjacent to the top side of encapsulant 250. In addition, bottom protrusion 255 provided on the bottom side of encapsulant 250 can compensate for such variations and electronic device 200 can be more accurately mounted to a next level of assembly, such as an external board.

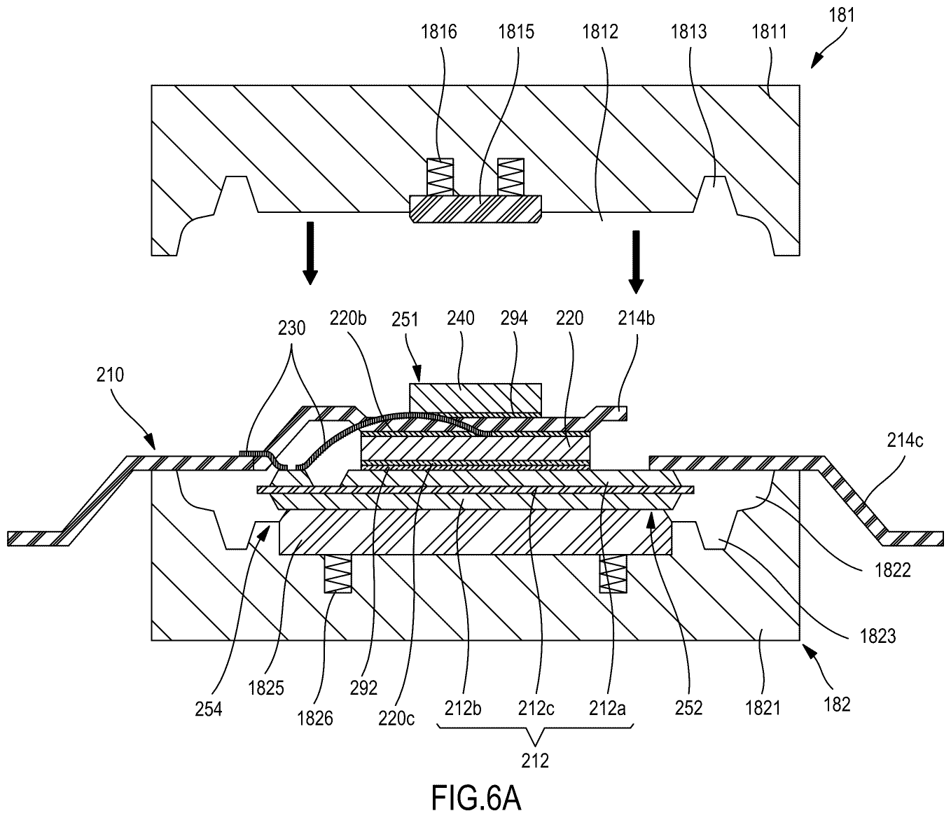

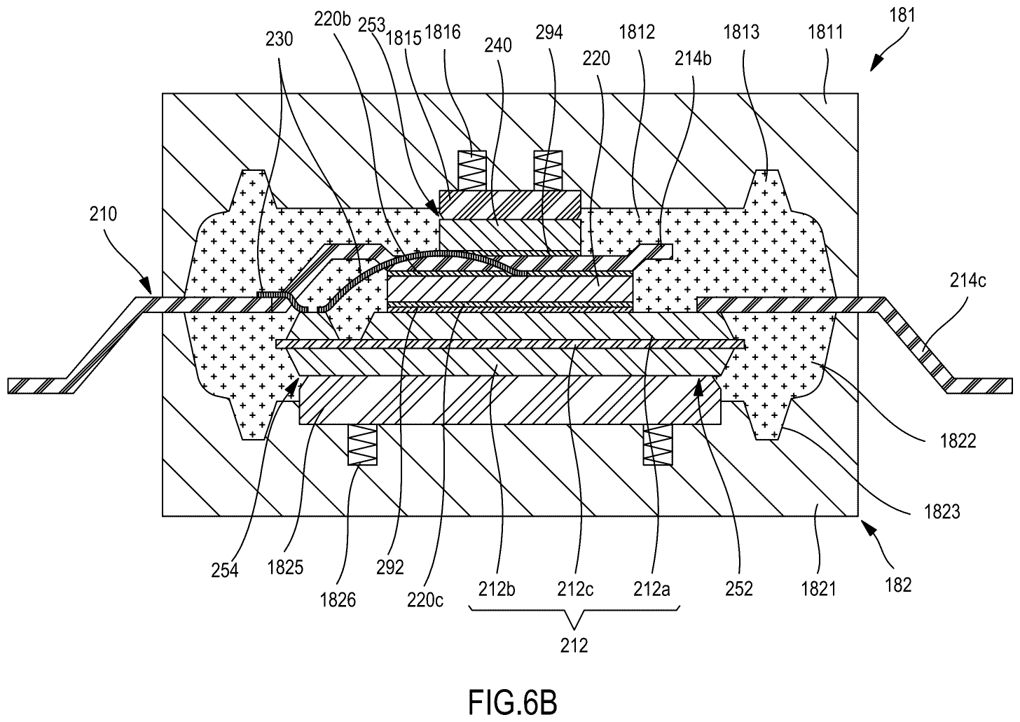

FIGS. 6A and 6B show cross-sectional views of an example method for manufacturing an electronic device, such as electronic device 200. The method for manufacturing electronic device 200 shown in FIGS. 6A and 6B can be similar to the method for manufacturing electronic device 100 shown in FIGS. 2A to 2D except for the configuration of electronic device 200. FIG. 6A shows a cross-sectional view of electronic device 200 at an early stage of manufacture including die paddle 212, electronic component 220, interconnects 130, leads 214, and heat sink 240 before encapsulant 250 is provided. In the example shown in FIG. 6A, electronic device 200 is placed between upper die set 181 and lower die set 182 of a mold apparatus.

Upper die set 181 can comprise upper die body 1811, upper cavity 1812 recessed inward from the lower side of upper die body 1811, upper holding plate 1815 provided on the upper side of upper cavity 1812, upper holding plate 1815 provided on the upper side of upper cavity 1812, and upper spring 1816 provided coupled between upper holding plate 1815 and upper die body 1811. In some examples, upper recess 1813 having a depth can be provided between the upper and lateral sides of upper cavity 1812. In some examples, upper recess 1813 can be similar to or correspond to the shape of top protrusion 256 of encapsulant 250.

In some examples, lower die set 182 can comprise lower die body 1821, lower cavity 1822 recessed downward on the upper side of lower die body 1821, lower holding plate 1825 provided on the lower side of lower cavity 1822, and lower spring 1826 provided coupled between lower holding plate 1825 and lower die body 1821. In some examples, lower recess 1823 having a depth can be provided between the lower side and the lateral sides of lower cavity 1822. In some examples, lower recess 1823 can be similar to or correspond to the shape of bottom protrusion 255 of encapsulant 250.

In some examples, electronic device 200 can be placed between placed between upper die set 181 and lower die set 182, which are initially vertically separated and spaced apart from each other. For example, lower conductor 212b of die paddle 112 can be placed on lower holding plate 1825. In some examples, die paddle 112 can be placed in an uneven or non-flat state inside lower die set 182.

FIG. 6B shows a cross-sectional view of electronic device 200 at a later stage of manufacture. In the example shown in FIG. 6B, electronic device 200 can be clamped between upper die set 181 and lower die set 182. Upper holding plate 1815 of upper die set 181 can elastically press the upper side of heat sink 240 due to an elastic force applied by upper spring 1816. In some examples, the horizontal width of upper holding plate 1815 can be smaller than the horizontal width of heat sink 240. In some examples, the upper circumference or top side peripheral edge of heat sink 240 can be exposed through the lateral or chamfered sides of upper holding plate 1815 to provide space for top extension region 253. In some examples, upper recess 1813 of upper die set 181 can be located outside the lateral sides of heat sink 240. In some examples, lower holding plate 1825 can elastically press the bottom side of die paddle 212 due to an elastic force applied by lower spring 1826. In some examples, the horizontal width of lower holding plate 1825 can be smaller than the horizontal width of die paddle 212. In some examples, the lower circumference or bottom side peripheral edge of die paddle 212 can be exposed through the lateral sides of lower holding plate 1825 to provide space for bottom extension region 254. In some examples, lower recess 1823 of lower die set 182 can be located outside the lateral sides of die paddle 212.

In this way, electronic device 200 can be clamped in an even and flat state between upper die set 181 and lower die set 182. In addition, by the clamping, warpage of electronic device 200 can be reduced and burr defects or defects caused by burrs can be prevented or reduced.

In some examples, encapsulant 250 can be provided between upper cavity 1812 of upper die set 181 and lower cavity 1822 of lower die set 182. In some examples, molten encapsulant 250 can flow into upper cavity 1812 and lower cavity 1822 through a gate provided in upper die set 181 or lower die set 182. In this way, encapsulant 250 can cover and surround die paddle 212, electronic component 220, interconnects 230, leads 214, and heat sink 240. In some examples, encapsulant 250 can form top extension region 253 by surrounding the lateral sides of upper holding plate 1815 and the vicinity of the top side peripheral edge of heat sink 240. In some examples, top extension region 253 can comprise sloped sidewalls as defined the shape of upper holding plate 1815. In some examples, encapsulant 250 can form top protrusion 256 protruding upward from the lateral sides of heat sink 240. In some examples, encapsulant 250 can form bottom extension region 254 by surrounding the lateral sides of lower holding plate 1825 and the vicinity of the bottom side peripheral edge of die paddle 212. In some examples, encapsulant 250 can form a bottom protrusion 255 protruding downward from the lateral sides of die paddle 212.

In some examples, electronic device 200 provided with encapsulant 250 can be taken out from upper die set 181 and lower die set 182. In some examples, after curing of encapsulant 250 is completed, upper die set 181 and lower die set 182 can be separated from each other, and electronic device 200 can be separated from upper die set 181 or lower die set 182. In this way, electronic device 200 is provided comprising heat sink 240 exposed from encapsulant 250 at the top side and die paddle 212 exposed from encapsulant 250 at bottom side. Also, top extension region 253 of encapsulant 150 is provided covering the upper circumference or top side peripheral edge of heat sink 240. In some examples, top protrusion 256 of encapsulant 250 can be provided on the circumference of top extension region 253. In some examples, bottom extension region 254 of encapsulant 250 can be provided on the lower circumference or bottom side peripheral edge of die paddle 212. In some examples, bottom protrusion 255 of encapsulant 250 can be provided on the circumference of bottom extension region 254.

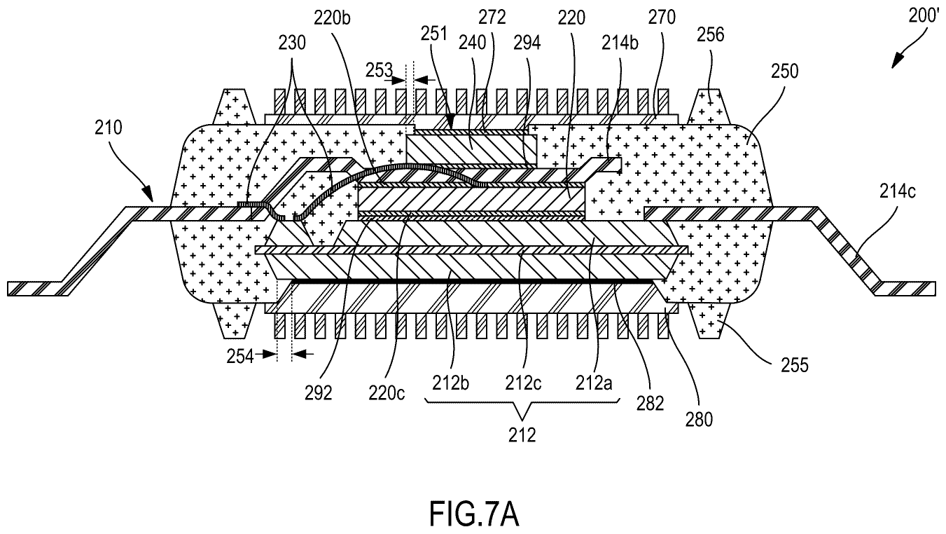

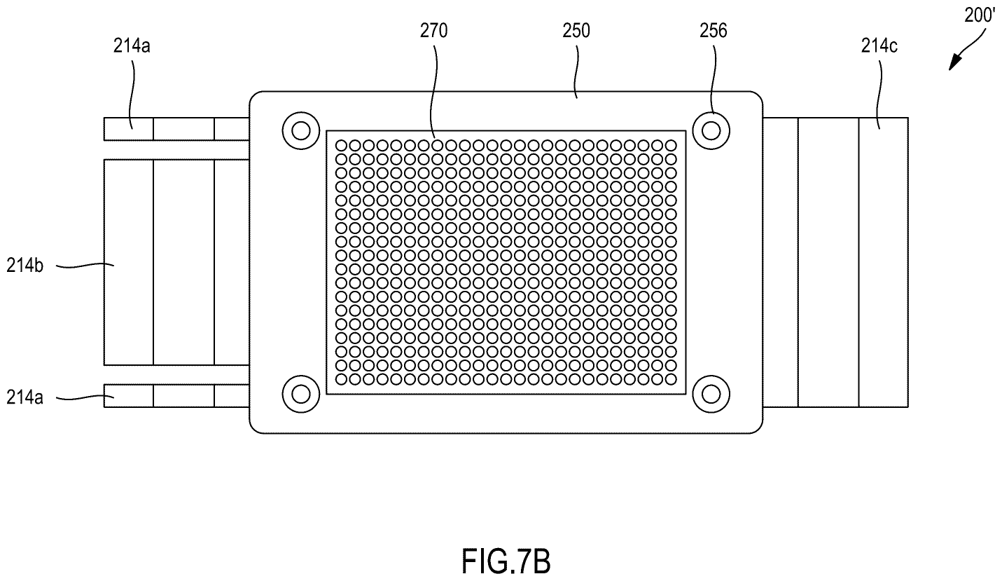

FIGS. 7A and 7B show a cross-sectional view and a top view of an example electronic device 200′. Electronic device 200′ shown in FIGS. 7A and 7B can be similar to electronic device 200 shown in FIG. 5A, except top heat spreader 270 and bottom heat spreader 280 are provided. In the example shown in FIGS. 7A and 7B, top heat spreader 270 can be coupled to heat sink 240. In some examples, the horizontal width of top heat spreader 270 can be greater than the horizontal width of heat sink 240. In some examples, top heat spreader 270 can be provided overlapping onto the top side of encapsulant 250 around heat sink 240 (e.g., including top extension region 253). In some examples, the width of top heat spreader 270 is greater than the width of electronic component 220. In some examples, top heat spreader 270 can comprise a plurality of heat radiation fins to further improve heat dissipation performance. In some examples, top heat spreader 270 can be attached to heat sink 240 via top heat spreader attach material 272. In some examples, top heat spreader 270 can be in contact with top extension region 253 of encapsulant 250 or the top side of encapsulant 250. Top heat spreader 270 is configured to radiate heat generated from electronic component 220 together with heat sink 240.

In the example shown in FIGS. 7A and 7B, bottom heat spreader 280 can be provided on die paddle 212. In some examples, bottom heat spreader 280 can be coupled to lower conductor 212b. In some examples, the horizontal width of bottom heat spreader 280 can be greater than the horizontal width of lower conductor 212b. In some examples, bottom heat spreader 280 can be provided not only on the bottom side of lower conductor 212b but also on the bottom side of encapsulant 250 around lower conductor 212b (e.g., including bottom extension region 254). In some examples, bottom heat spreader 280 can comprise a plurality of heat radiation fins to further improve heat dissipation performance. In some examples, bottom heat spreader 280 can be attached to lower conductor 212b via bottom heat spreader attach material 282 (e.g., an adhesive, an attach tape, an attach film, a TIM, or a solder). In some examples, bottom heat spreader 280 can be in contact with bottom extension region 254 of encapsulant 250 or the bottom side of encapsulant 250. Bottom heat spreader 280 is configured to radiate heat generated from electronic component 220 together with die paddle 212.

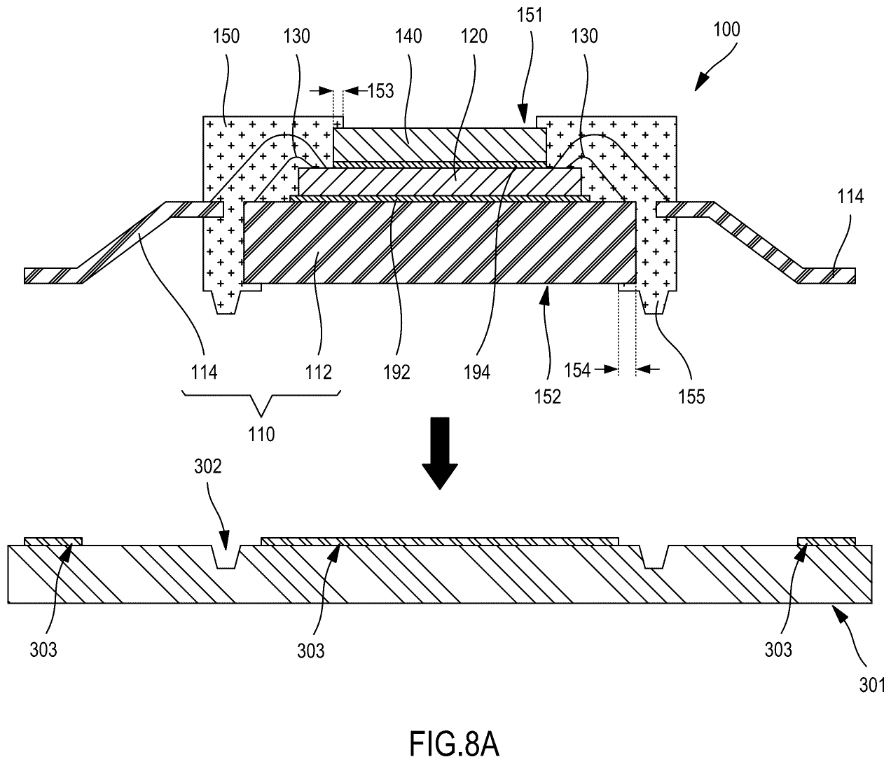

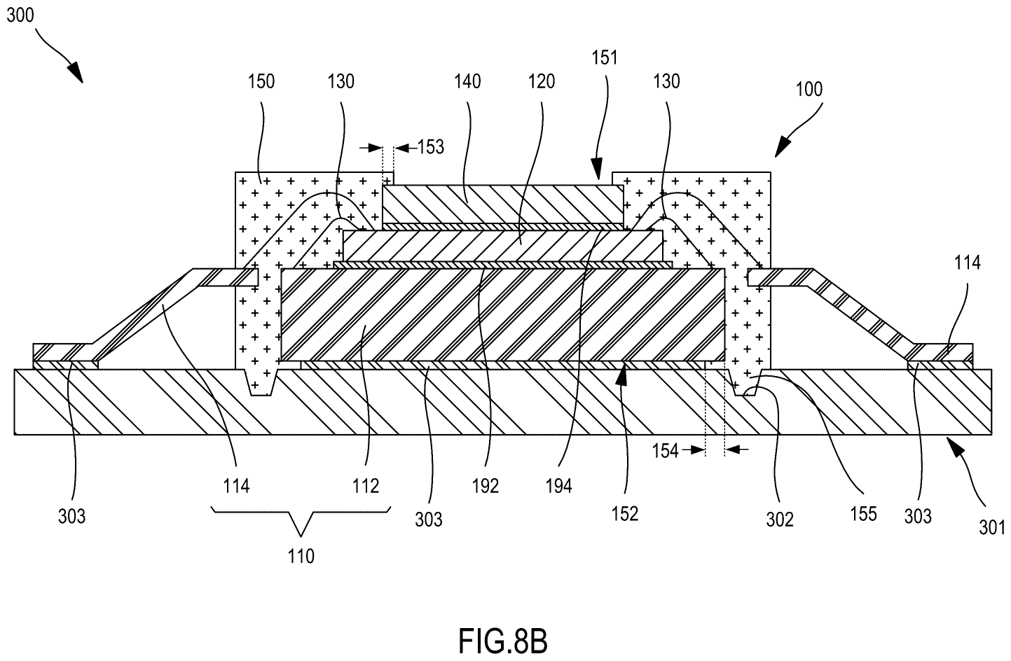

FIGS. 8A and 8B show cross-sectional views of an example method for manufacturing an example electronic device 300, which includes electronic device 100 shown in FIG. 1 coupled to a base substrate 301. In the example shown in FIGS. 8A and 8B, base substrate 301 comprise an upper side, a lower side opposite to the upper side, and a substrate groove 302, which extends inward from the upper side. In some examples, substrate groove 302 is configured to conform to or engage with bottom protrusion 155 of electronic device 300. In some examples, bottom protrusion 155 of electronic device 100 is within substrate groove 302. Accordingly, the mounting accuracy of electronic device 300 with respect to base substrate 301 can be improved.

In some examples, base substrate 301 can comprise or be referred to as a printed circuit board (PCB), a rigid PCB, a flexible PCB, a high-density interconnection (HDI) board, Rigid-Flexible (RF) PCB, a multi-layer board (MLB) board, a substrate like PCB (SLP), a redistribution layer (RDL) substrate, a core substrate, or a packaging substrate. In some examples, base substrate 301 can be provided with a conductive wiring pattern on the surface or inside using a dielectric layer as a base. Accordingly, leads 114 of electronic device 300 can be connected to the conductive wiring pattern through conductive device interface material 303. In some examples, conductive device interface material 303 is first provided on the upper side of base substrate 301 before electronic device 100 is attached. In some examples, device interface material 303 on die paddle 112 before electronic device 100 is attached to base substrate 301. In some examples, conductive device interface material 303 can comprise solder or conductive paste. In some examples, the thickness of conductive device interface material 303 can be similar to the thickness of bottom extension region 154 of encapsulant 150. In some examples, bottom extension region 154 comprises a first thickness and conductive device interface material 303 comprises a second thickness substantially equal to the first thickness. In some examples, conductive device interface material 303 does not overlap onto the bottom surface of bottom extension region 154.

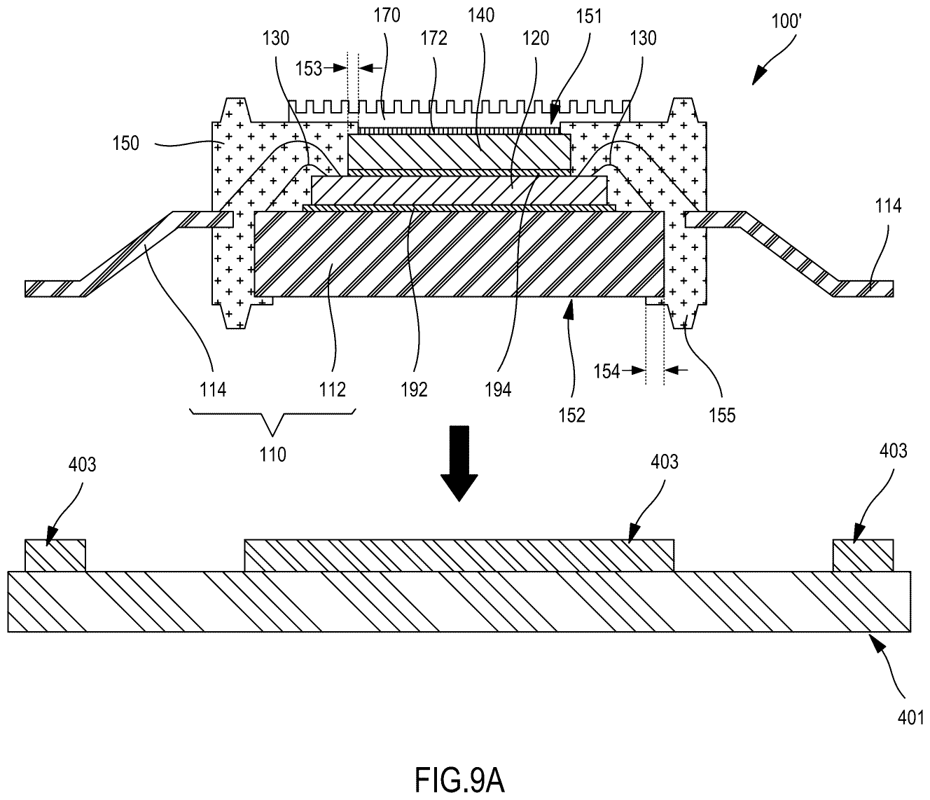

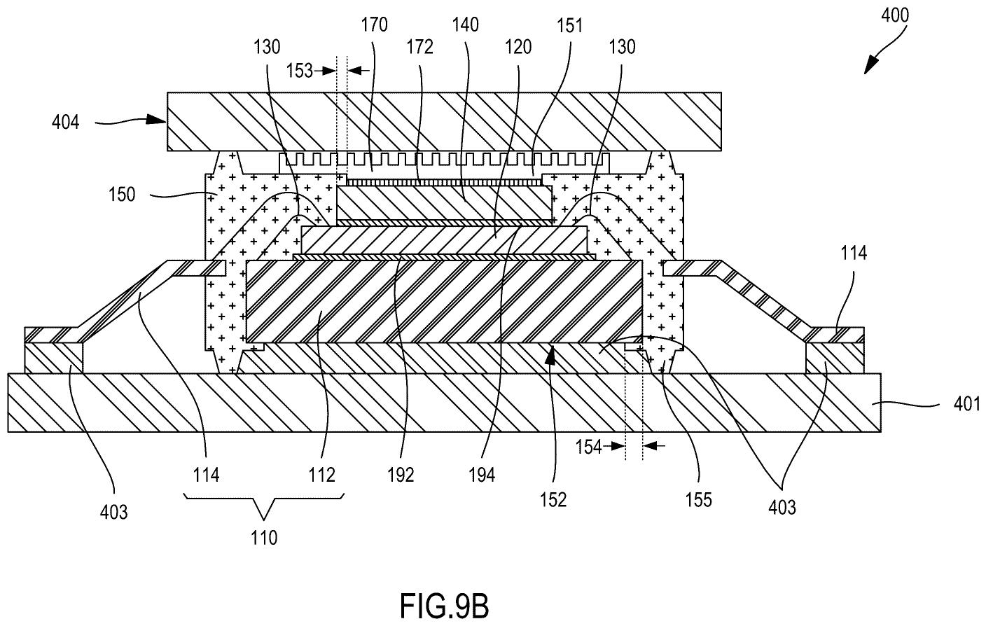

FIGS. 9A and 9B show cross-sectional views of an example method for manufacturing an example electronic device 400, which includes electronic device 100′ shown in FIG. 4 and a base substrate 401. The method for manufacturing electronic device 400 shown in FIGS. 9A and 9B can be similar to the method for manufacturing electronic device 300 shown in FIGS. 8A and 8B, except based substrate 401 is provided without a substrate groove. In the example shown in FIGS. 9A and 9B, base substrate 401 can comprise an upper side and a lower side opposite to the upper side. Die paddle 112 and leads 114 of electronic device 100′ can be coupled to base substrate 401 through conductive device interface material 403. In some examples, bottom protrusion 155 of electronic device 400 can be in contact with the upper side of base substrate 401. In some examples, the thickness of conductive device interface material 403 can be similar to the combined thicknesses of bottom extension region 154 and bottom protrusion 155. In some examples, conductive device interface material 403 can be in contact with the surfaces of bottom extension region 154 and bottom protrusion 155. In this way, relatively thick conductive interface material 403 can be interposed between die paddle 112 and base substrate 401, thereby improving mounting reliability. In some examples, bottom protrusion 155 is configured to retain conductive device interface material 403 below die paddle 112 and bottom extension region 154.

In some examples, upper component 404 can be coupled to top protrusion 156 of electronic device 100′. In some examples, upper component 404 comprises a thermally conductive material and can be in contact with heat spreader 170. In some examples, upper component 404 can comprise a cap or lid and can be spaced apart from heat spreader 170. Upper component 404 and can protect heat spreader 170 from external environments.

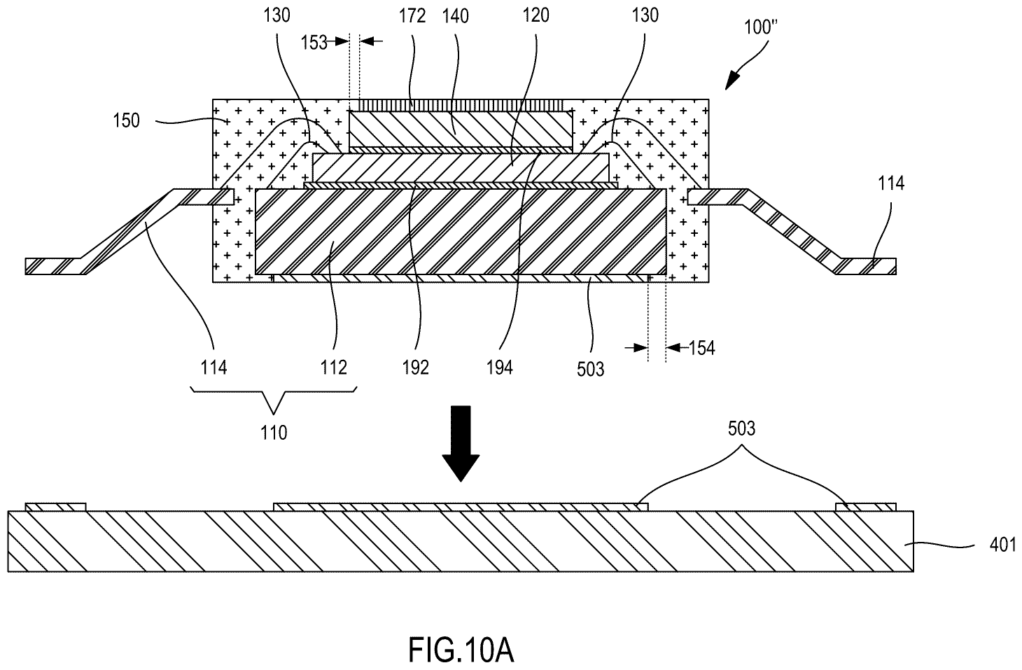

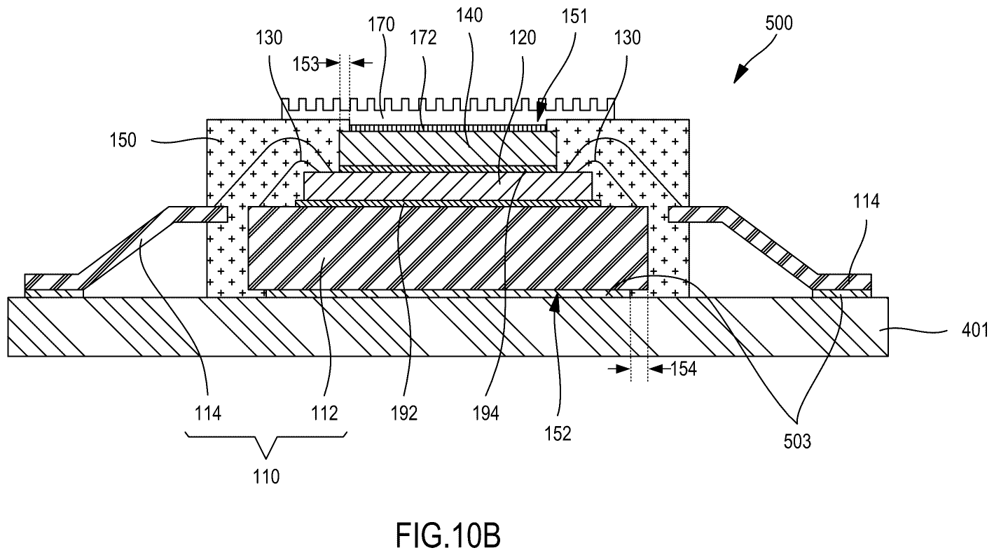

FIGS. 10A and 10B show cross-sectional views of an example method for manufacturing an example electronic device 500, which can comprise electronic device 100″ coupled to base substrate 401. Electronic device 100″ can be similar to electronic device 100A shown in FIG. 3 except electronic device 100″ includes head spreader 170 coupled to heat sink 140. The method for manufacturing electronic device 500 shown in FIGS. 10A and 10B can be similar to the method for manufacturing electronic device 400 shown in FIGS. 9A and 9B, except where electronic device 100″ is mounted on base substrate 401 after electronic device 100″ is provided with conductive device interface material 503. In the example shown in FIGS. 10A and 10B, conductive device interface material 503 can be provided on the bottom side or lower region of die paddle 112 exposed through bottom extension region 154. In some examples, conductive device interface material 172 can be provided on the top side of heat sink 140 exposed through top extension region 153.

In some examples, the upper side of base substrate 401 also can be provided with conductive device interface material 503 before electronic device 100″ is attached. During the mounting process of electronic device 100″, conductive device interface material 503 on die paddle 112 and conductive device interface material 503 on base substrate 401 can be adhered to each other. In some examples, heat spreader 170 can be attached to heat sink 140 with conductive device interface material 172 provided on heat sink 140. In some examples, through a mass reflow process, electronic device 100″ (e.g., die paddle 112 and leads 114) and base substrate 401 can be coupled to each other, and heat spreader 170 can be coupled to heat sink 140. Accordingly, increased flexibility can be provided during the mounting process of electronic device 100″. In some examples, on the bottom side of encapsulant 150, only bottom extension region 154 exists and a bottom protrusion can be omitted. In some examples, on the top side of encapsulant 150, only top extension region 153 exists and a top protrusion can be omitted. Accordingly, bottom extension region 154 of encapsulant 150 can be in contact with base substrate 401, and top extension region 253 of encapsulant 150 can be in contact with heat spreader 280.

It is understood that the various elements described herein can be combined in other examples of electronic devices.

In summary, structures and associated methods that relate to packaged electronic devices having improved manufacturability and quality have been described. More particularly, structures and methods are described that compensate for dimensional variations and protect exposed surfaces of components, such as heat sinks or die pads, during manufacturing thereby reducing defects and damage to the components. In some examples, structures are provided that cover sensitive regions of the components. In some examples, molded structures are provided that include extension portions that overlap corner portions and laterally overlap peripheral edge portions of the components. In some examples, the extension portions can be used with a mold apparatus during molding to apply pressure to sensitive portions of the components to suppress the formation of burrs and other defects thereby improving quality. In some examples, the molded structures include protruding portions that can be used for more accurate alignment with other structures, such as assembly boards or other electronic devices, thereby improving manufacturability. In addition, the protrusions and the extensions can compensate for non-flat components and other imperfections to further improve manufacturability.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

What is claimed is:

1. An electronic device, comprising:
a substrate comprising:
a die paddle comprise a top side, a bottom side opposite to the top side, a lateral side connecting the top side of the die paddle to the bottom side of the die paddle, and a bottom side peripheral edge; and
leads spaced apart from the die paddle;
an electronic component comprising a component top side and a component bottom side opposite to the component top side, wherein:
the component bottom side is coupled to the top side of the die paddle; and
the electronic component is coupled to the leads;
a heat sink coupled to the component top side and comprising a top side, a bottom side opposite to the top side of the heat sink, a lateral side connecting the top side of the heat sink to the bottom side of the heat sink, and a top side peripheral edge; and
an encapsulant covering the die paddle, the leads, the electronic component, and the heat sink, wherein:
the encapsulant comprises an encapsulant top side, an encapsulant bottom side opposite to the encapsulant top side, an encapsulant lateral side connecting the encapsulant top side to the encapsulant, and a top extension region;
the top side of the heat sink is exposed from the encapsulant top side;
the bottom side of the die paddle is exposed from the encapsulant bottom side;
parts of the leads are exposed from the encapsulant lateral side; and
the top extension region of the encapsulant covers the top side peripheral edge of the heat sink.

2. The electronic device of claim 1, wherein:
the encapsulant comprises a bottom extension region; and
the bottom extension region of the encapsulant covers the bottom side peripheral edge of the die paddle.

3. The electronic device of claim 2, further comprising:
a head spreader coupled to the bottom side of the die paddle and overlapping the bottom extension region of the encapsulant.

4. The electronic device of claim 1, wherein:
the encapsulant comprises a bottom protrusion extending outward from the encapsulant bottom side.

5. The electronic device of claim 4, further comprising:
a base substrate comprising an upper side and a substrate groove extending inward from the upper side; and
a conductive device interface material;
wherein:
the bottom side of the die paddle is attached to the base substrate with the conductive device interface material; and
the bottom protrusion is within the substrate groove.

6. The electronic device of claim 5, wherein:
the encapsulant comprises a bottom extension region;
the bottom extension region of the encapsulant covers the bottom side peripheral edge of the die paddle;
the bottom extension region comprises a first thickness; and
the conductive device interface material comprises a second thickness substantially equal to the first thickness.

7. The electronic device of claim 1, further comprising:
a heat spreader coupled to the top side of the heat sink and overlapping the top extension region of the encapsulant.

8. The electronic device of claim 1, further comprising:
a top protrusion extending outward from the encapsulant top side.

9. The electronic device of claim 8, further comprising:
an upper component coupled to the top protrusion.

10. The electronic device of claim 1, wherein:
the bottom side of the die paddle is coplanar with the encapsulant bottom side.

11. The electronic device of claim 1, wherein:
the leads comprise a first lead coupled to the component top side; and
the heat sink is attached to the first lead.

12. The electronic device of claim 1, wherein:
the die paddle comprises:
an upper conductor;
a lower conductor; and
a core layer comprising an insulator interposed between the upper conductor and the lower conductor; and
one of the leads is attached to the upper conductor.

13. An electronic device, comprising:
a die pad comprising a top side, a bottom side opposite to the top side, a lateral side connecting the top side of the die pad to the bottom side of the die pad, and a bottom side peripheral edge;
leads spaced apart from the die pad;
an electronic component coupled to the leads and comprising a component top side and a component bottom side opposite to the component top side, the component bottom side coupled to the top side of the die pad;
a heat sink comprising a top side, a bottom side opposite to the top side of the heat sink, a lateral side connecting the top side of the heat sink to the bottom side of the heat sink, and a top side peripheral edge the bottom side of the heat sink is coupled to the component top side; and
an encapsulant covering the die pad, the leads, the electronic component, and the heat sink, wherein:
the encapsulant comprises an encapsulant top side, an encapsulant bottom side opposite to the encapsulant top side, an encapsulant lateral side connecting the encapsulant top side to the encapsulant, a top extension region, and a bottom extension region;
the top side of the heat sink is exposed from the encapsulant top side;
the bottom side of the die pad is exposed from the encapsulant bottom side;
parts of the leads are exposed from the encapsulant lateral side;
the top extension region of the encapsulant covers the top side peripheral edge of the heat sink; and
the bottom extension region of the encapsulant covers the bottom side peripheral edge of the die pad.

14. The electronic device of claim 13, wherein:
the electronic component comprises a first width;
the heat sink comprises a second width less than the first width;
the encapsulant top side is above the top side of the heat sink; and
the encapsulant bottom side is below the bottom side of the die pad.

15. The electronic device of claim 13, wherein:
the encapsulant comprises a bottom protrusion extending outward from the encapsulant bottom side.

16. The electronic device of claim 13, further comprising:
a heat spreader coupled to the bottom side of the die pad.

17. A method of manufacturing an electronic device, comprising:
providing a substrate comprising:
a die paddle comprise a top side, a bottom side opposite to the top side, a lateral side connecting the top side of the die paddle to the bottom side of the die paddle, and a bottom side peripheral edge; and
leads spaced apart from the die paddle;
providing an electronic component comprising a component top side and a component bottom side opposite to the component top side, the component bottom side coupled to the top side of the die paddle;
coupling the electronic component to the leads;
providing a heat sink comprising a top side, a bottom side opposite to the top side of the heat sink, a lateral side connecting the top side of the heat sink to the bottom side of the heat sink, and a top side peripheral edge, the bottom side of the heat sink coupled to the component top side; and
providing an encapsulant covering the die paddle, the leads, the electronic component, and the heat sink, wherein:
the encapsulant comprises an encapsulant top side, an encapsulant bottom side opposite to the encapsulant top side, an encapsulant lateral side connecting the encapsulant top side to the encapsulant, and a top extension region;
the top side of the heat sink is exposed from the encapsulant top side;
the bottom side of the die paddle is exposed from the encapsulant bottom side;
parts of the leads are exposed from the encapsulant lateral side; and
the top extension region of the encapsulant covers the top side peripheral edge of the heat sink.

18. The method of claim 17, wherein:
providing the encapsulant comprises providing a bottom extension region; and
the bottom extension region of the encapsulant covers the bottom side peripheral edge of the die paddle.

19. The method of claim 18, further comprising:
providing a head spreader coupled to the bottom side of the die paddle and overlapping the bottom extension region of the encapsulant.

20. The method of claim 17, further comprising:
providing a heat spreader coupled to the top side of the heat sink and overlapping the top extension region of the encapsulant,
wherein:
providing the encapsulant comprises providing a bottom protrusion extending outward from the encapsulant bottom side.
